(19) United States
(12) Patent Application Publication
(10) Pub. No.: US 2015/0144318 A1
(43) Pub. Date: May 28, 2015

(54) HEAT DISSIPATING DEVICE AND METHOD OF MANUFACTURING THE SAME

(71) Applicant: Cooler Master (Hui Zhou) Co., Ltd., Huizhou (CN)

(72) Inventors: Chia-Yu Lin, Huizhou (CN); Qingsong Zhang, Huizhou (CN); Tao Song, Huizhou (CN)

(21) Appl. No.: 14/503,426

(22) Filed: Oct. 1, 2014

(30) Foreign Application Priority Data
Nov. 26, 2013 (CN) 201310611071.0

(51) Int. Cl. H05K 7/20; B23P 15/26; F28F 3/00

(52) U.S. Cl. CPC H05K 7/2039; F28F 3/00; B23P 15/26
USPC 165/185; 29/890.03

(57) ABSTRACT

A heat dissipating device includes a base and a heat dissipating fin. The base includes an accommodating recess formed thereon. The heat dissipating fin includes a heat dissipating portion and a protruding portion, wherein the protruding portion protrudes from an end of the heat dissipating portion and is disposed in the accommodating recess. The base and the heat dissipating fin are combined with each other by a punching process, such that a first side wall of the accommodating recess covers at least a part of the protruding portion.

### BACKGROUND OF THE INVENTION

1. Field of the Invention

The invention relates to a heat dissipating device and a method of manufacturing the same and, more particularly, to a heat dissipating device utilizing a punching process to combine a base and a heat dissipating fin and a method of manufacturing the same.

2. Description of the Prior Art

Heat dissipating device is a significant component for electronic products. When an electronic product is operating, the current in circuit will generate unnecessary heat due to impedance. If the heat is accumulated in the electronic components of the electronic product without dissipating immediately, the electronic components may get damage due to the accumulated heat. Therefore, the performance of heat dissipating device is a significant issue for the electronic product.

Referring to FIG. 1, FIG. 1 is a schematic view illustrating a heat dissipating device 1 of the prior art. As shown in FIG. 1, a heat dissipating fin 12 is disposed on a base 10 of the heat dissipating device 1. As shown in FIG. 1, the heat dissipating fin 12 is formed with the base 10 integrally by a die casting process. Due to the requirement of mold stripping during the die casting process, the heat dissipating fin 12 has a draft angle α between 2 degrees and 3 degrees, such that the whole weight of the fin is heavy and the height of the fin is limited. Furthermore, the number of heat dissipating fins is reduced in the heat dissipating device due to the draft angle α, such that the heat dissipating area is not enough and the heat dissipating efficiency is worse.

### SUMMARY OF THE INVENTION

The invention provides a heat dissipating device utilizing a punching process to combine a base and a heat dissipating fin and a method of manufacturing the same, so as to solve the aforesaid problems.

According to an embodiment of the invention, a heat dissipating device comprises a base and a heat dissipating fin. The base comprises an accommodating recess formed thereon. The heat dissipating fin comprises a heat dissipating portion and a protruding portion, wherein the protruding portion protrudes from an end of the heat dissipating portion and is disposed in the accommodating recess. The base and the heat dissipating fin are combined with each other by a punching process, such that a first side wall of the accommodating recess covers at least a part of the protruding portion.

According to another embodiment of the invention, a method of manufacturing a heat dissipating device comprises steps of providing a base and a heat dissipating fin, wherein the base comprises an accommodating recess formed thereon, the heat dissipating fin comprises a heat dissipating portion and a protruding portion, and the protruding portion protrudes from an end of the heat dissipating portion; disposing the protruding portion in the accommodating recess; and using a punching head to punch the base and the heat dissipating fin in a punching process, such that a first side wall of the accommodating recess covers at least apart of the protruding portion.

As mentioned in the above, the invention utilizes the punching process to combine the base and the heat dissipating fin. After the punching process, the side wall of the accommodating recess of the base will deform and then cover at least a part of the protruding portion of the heat dissipating fin, such that the base and the heat dissipating fin are combined with each other tightly. Accordingly, the draft angle of the conventional heat dissipating fin is unnecessary for the heat dissipating fin of the invention. Furthermore, the whole weight of the heat dissipating fin of the invention can be lighter and the height of the heat dissipating fin of the invention can be higher than the prior art. Moreover, the number of heat dissipating fins of the invention can be increased in the heat dissipating device, such that the heat dissipating area can be increased and the heat dissipating efficiency can be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a heat dissipating device of the prior art.

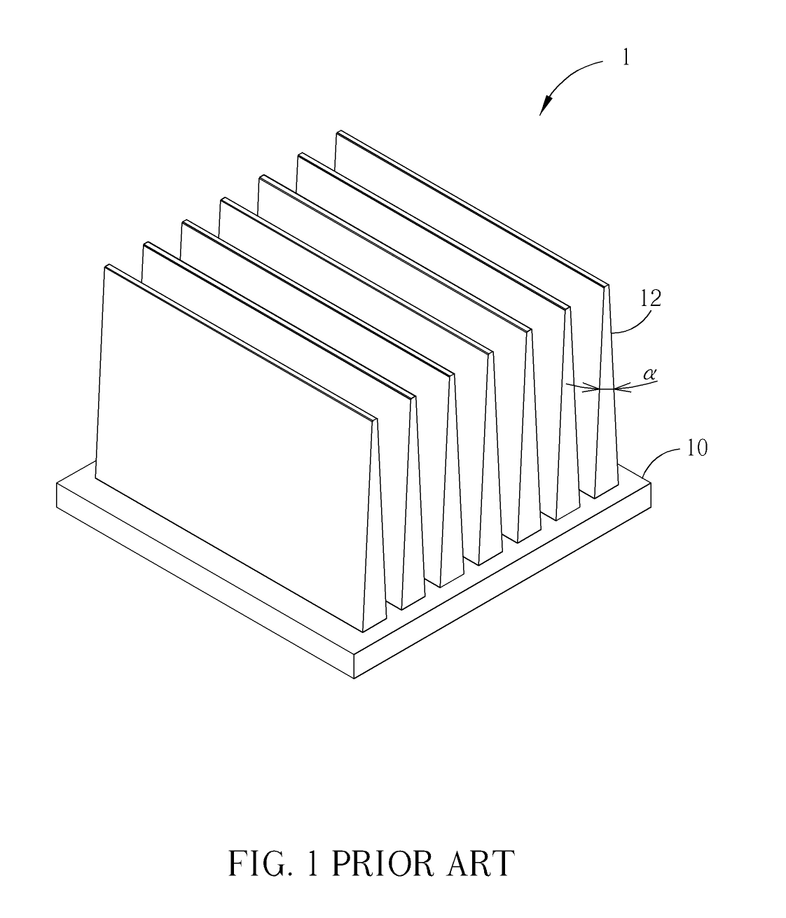

FIG. 2 is a perspective view illustrating a heat dissipating device according to a first embodiment of the invention.

FIG. 3 is a flowchart illustrating a method of manufacturing the heat dissipating device shown in FIG. 2.

FIG. 4 is a cross-sectional view illustrating the heat dissipating device along line A-A shown in FIG. 2.

FIG. 5 is a cross-sectional view illustrating the heat dissipating device shown in FIG. 4 before the punching process.

FIG. 6 is an exploded view illustrating the heat dissipating device shown in FIG. 5 before the punching process.

FIG. 7 is a perspective view illustrating the heat dissipating fin shown in FIG. 6 from another viewing angle.

FIG. 8 is a cross-sectional view illustrating a heat dissipating device before the punching process according to a second embodiment of the invention.

FIG. 9 is a cross-sectional view illustrating the heat dissipating device shown in FIG. 8 after the punching process.

### DETAILED DESCRIPTION

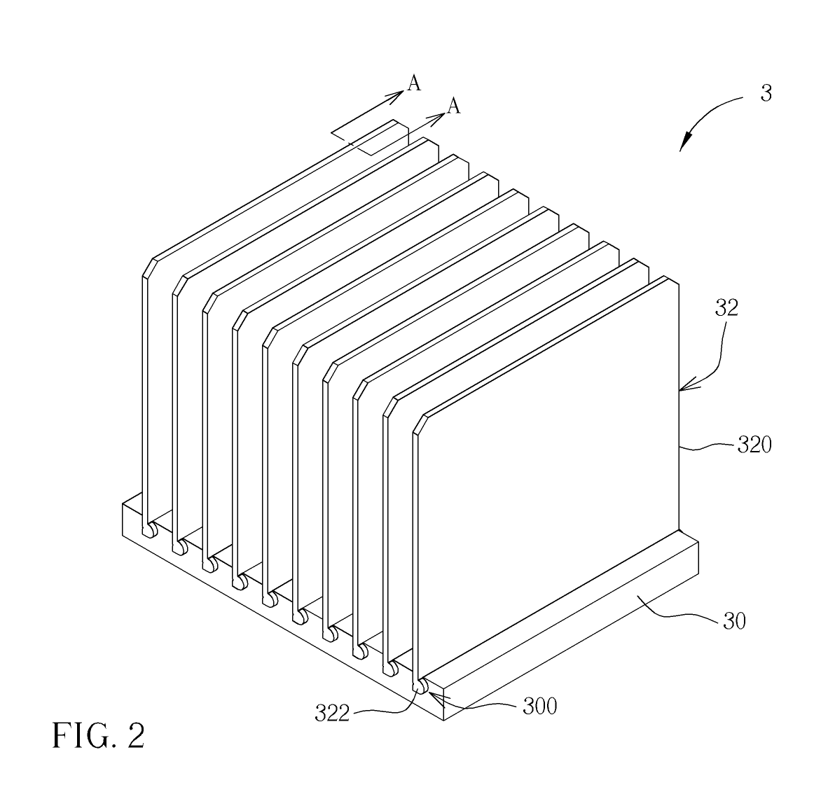

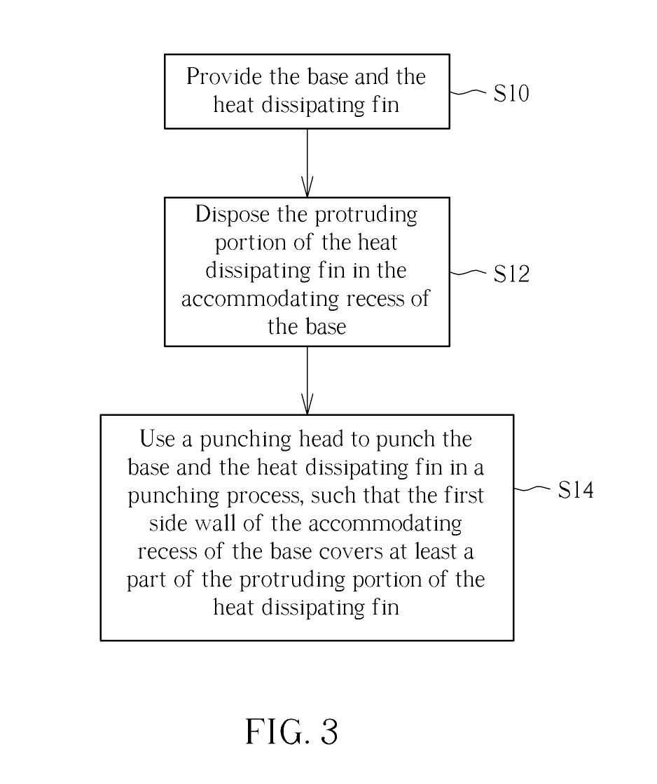

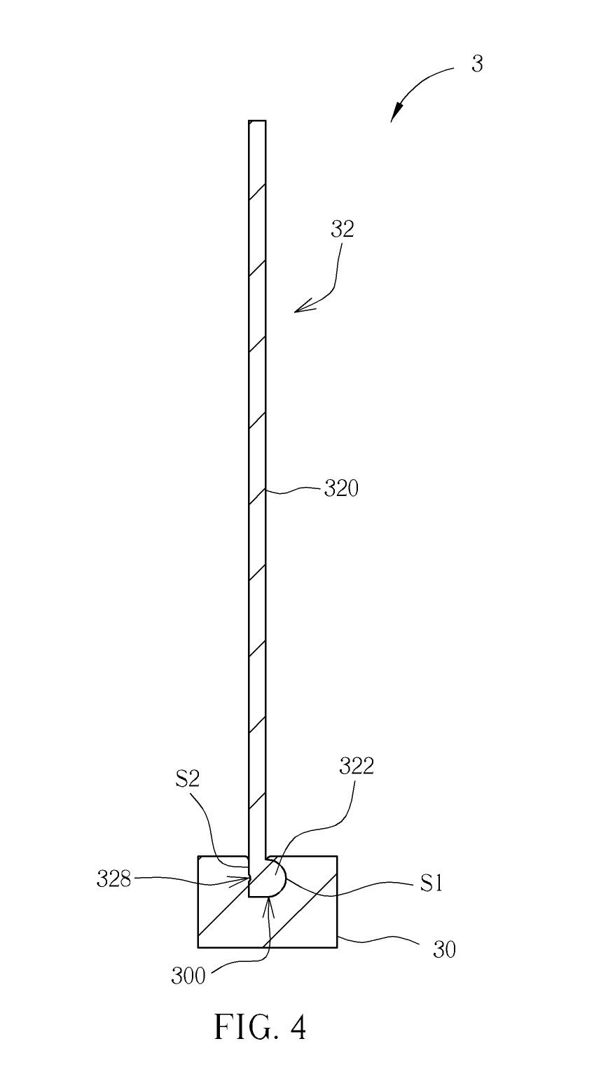

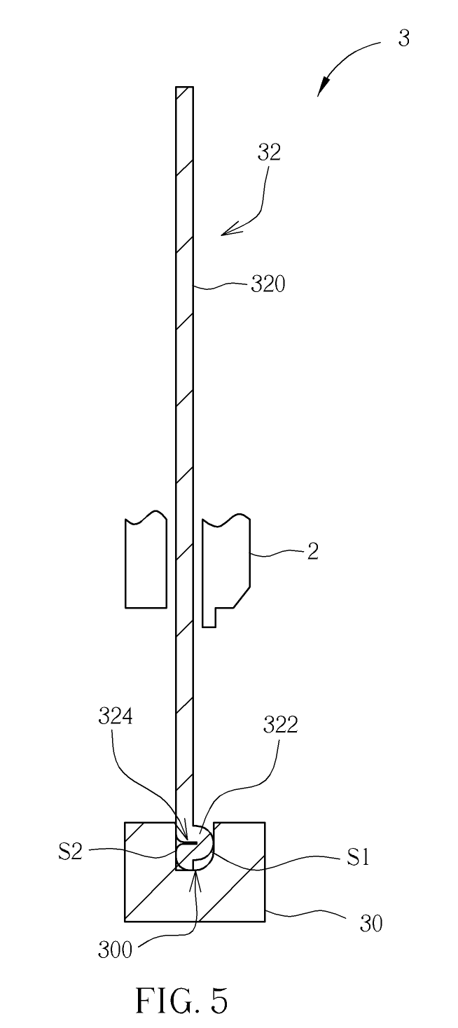

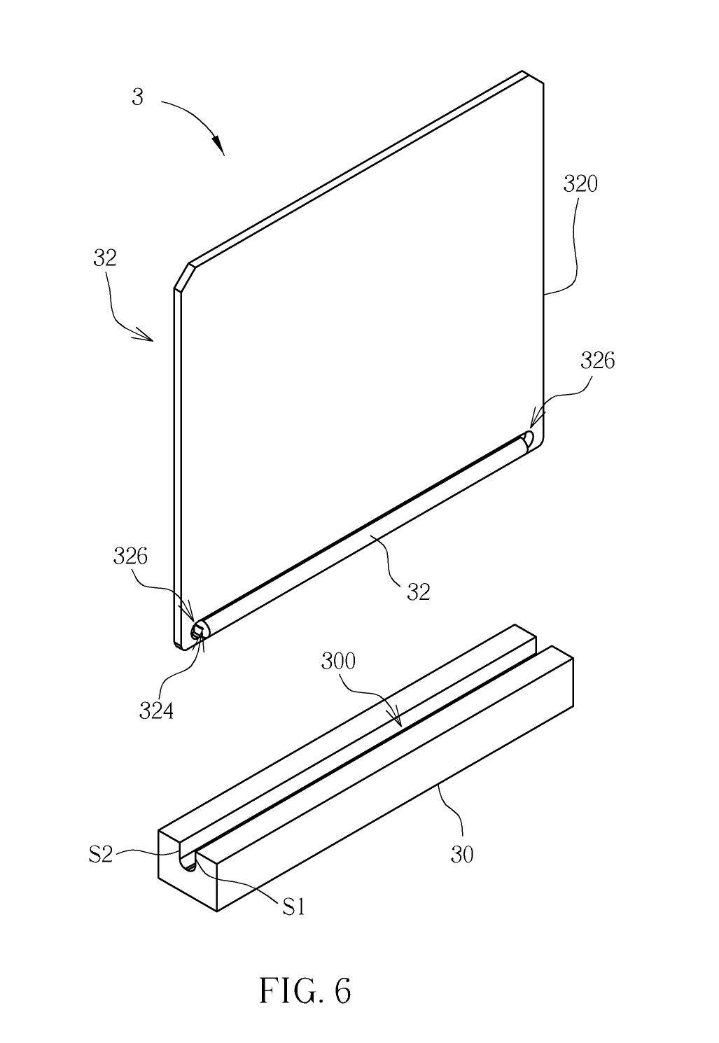

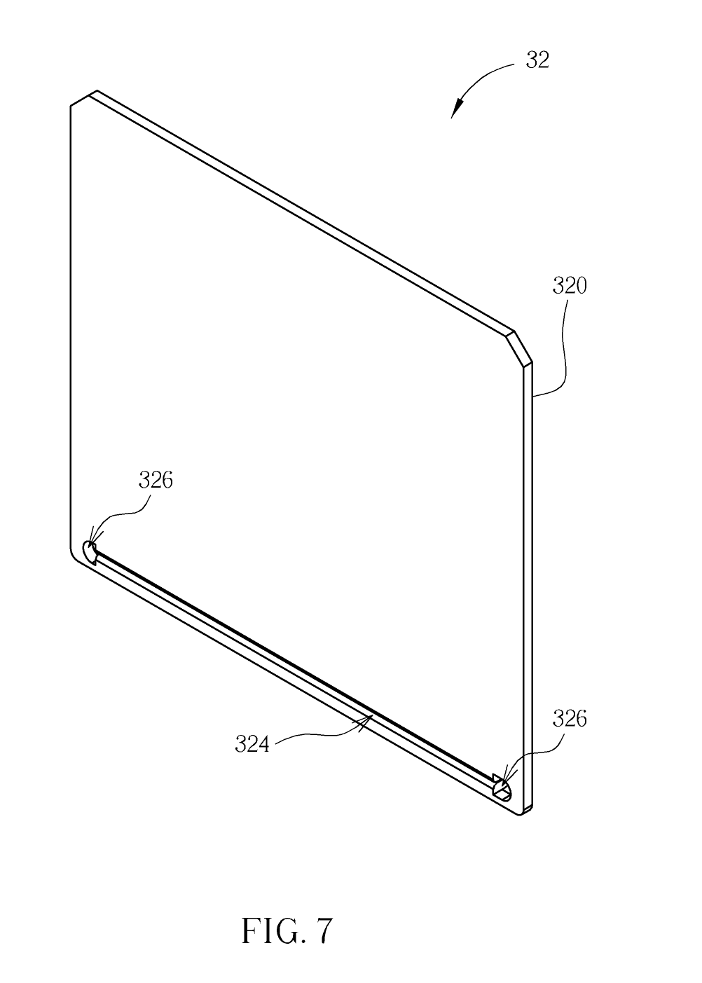

Referring to FIGS. 2 to 7, FIG. 2 is a perspective view illustrating a heat dissipating device 3 according to a first embodiment of the invention, FIG. 3 is a flowchart illustrating a method of manufacturing the heat dissipating device 3 shown in FIG. 2, FIG. 4 is a cross-sectional view illustrating the heat dissipating device 3 along line A-A shown in FIG. 2, FIG. 5 is a cross-sectional view illustrating the heat dissipating device 3 shown in FIG. 4 before the punching process, FIG. 6 is an exploded view illustrating the heat dissipating device 3 shown in FIG. 5 before the punching process, and FIG. 7 is a perspective view illustrating the heat dissipating fin 32 shown in FIG. 6 from another viewing angle.

As shown in FIG. 2, the heat dissipating device 3 of the invention comprises a base 30 and a plurality of heat dissipating fins 32, wherein the number of heat dissipating fins 32 can be determined according to practical applications and are not limited to the embodiment shown in FIG. 2. In this embodiment, the base 30 may be made of copper, aluminum or other heat conductive materials, and the heat dissipating fin 32 maybe made of aluminum or other heat conductive materials. As shown in FIG. 4, the base 30 comprises an accommodating recess 300 and the heat dissipating fin 32 comprises a heat dissipating portion 320 and a protruding portion 322, wherein the protruding portion 322 protrudes from an end of the heat dissipating portion 320 and is disposed in the accommodating recess 300. The base 30 and the heat dissipating fin 32 are combined with each other by a punching process, such that a first side wall S1 of the accommodating recess 300 covers at least apart of the protruding portion 322. Accordingly, the base 30 and the heat dissipating fin 32 are combined with each other tightly.

In this embodiment, the protruding portion 322 of the heat dissipating fin 32 may protrude from the end of the heat dissipating portion 320 by a drawing process, such that a slit 324 is formed on a side of the protruding portion 322 before the punching process, as shown in FIGS. 5 to 7. Accordingly, the protruding portion 322 is U-shaped before the punching process. Furthermore, the invention may form two holes 326 on opposite ends of the protruding portion 322, such that the protruding portion 322 can be formed by the drawing process more easily. In this embodiment, the protruding portion 322 is a strip-shaped structure continuously. However, in another embodiment, the protruding portion 322 may be a strip-shaped structure not continuously (e.g. like a broken line) and it depends on practical applications.

To manufacture the aforesaid heat dissipating device 3, first of all, step S10 shown in FIG. 3 is performed to provide the base 30 and the heat dissipating fin 32. Afterward, step S12 shown in FIG. 3 is performed to dispose the protruding portion 322 of the heat dissipating fin 32 in the accommodating recess 300 of the base 30. Finally, step S14 shown in FIG. 3 is performed to use a punching head 2 shown in FIG. 5 to punch the base 30 and the heat dissipating fin 32 in a punching process, such that the first side wall S1 of the accommodating recess 300 of the base 30 covers at least a part of the protruding portion 322 of the heat dissipating fin 32. As shown in FIGS. 4 and 5, the slit 324 is sealed to form an indentation 328 on the side of the protruding portion 322 after the punching process. Accordingly, a second side wall S2 of the accommodating recess 300 of the base 30 is engaged with the indentation 328 after the punching process, wherein the first side wall S1 is opposite to the second side wall S2. Since the first side wall S1 of the accommodating recess 300 covers at least a part of the protruding portion 322 and the second side wall S2 of the accommodating recess 300 is engaged with the indentation 328, the base 30 and the heat dissipating fin 32 can be combined with each other more tightly. It should be noted that the punching head 2 may be designed in appropriate shape, such that the first side wall S1 of the accommodating recess 300 of the base 30 may cover the protruding portion 322 of the heat dissipating fin 32 completely after the punching head 2 punches the base 30 and the heat dissipating fin 32.

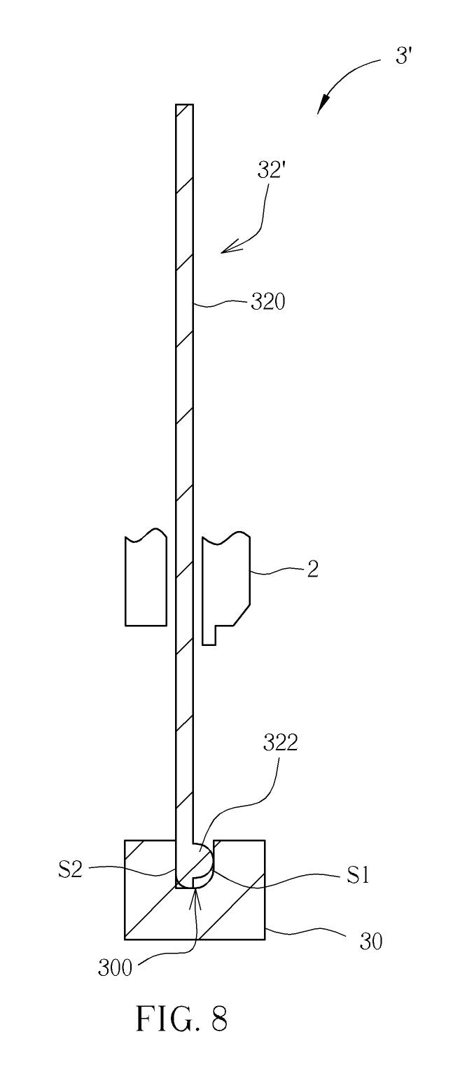

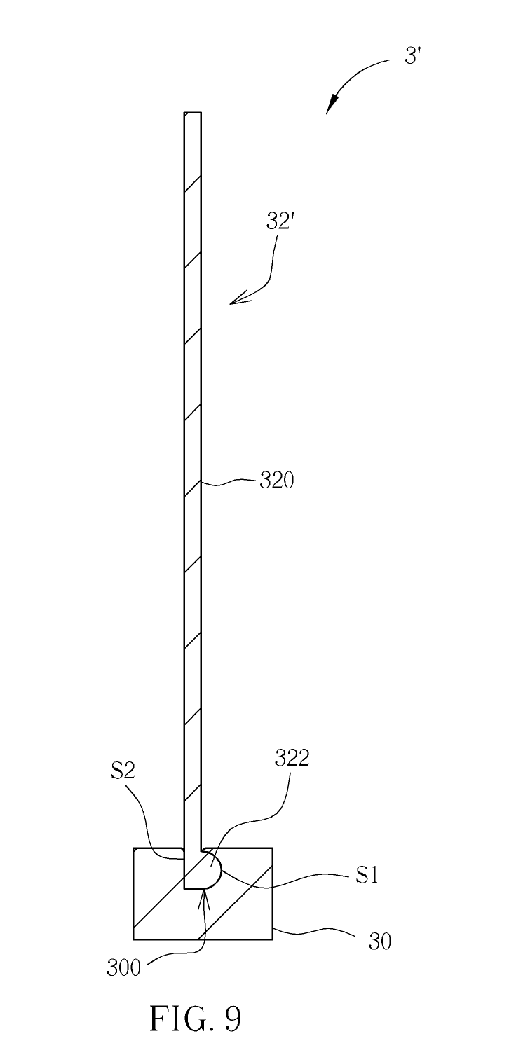

Referring to FIGS. 8 and 9 along with FIGS. 4 and 5, FIG. 8 is a cross-sectional view illustrating a heat dissipating device 3′ before the punching process according to a second embodiment of the invention, and FIG. 9 is a cross-sectional view illustrating the heat dissipating device 3′ shown in FIG. 8 after the punching process. The difference between the heat dissipating device 3′ and the aforesaid heat dissipating device 3 is that the heat dissipating fin 32′ of the heat dissipating device 3′ is formed by a die casting process. As shown in FIG. 8, since the heat dissipating fin 32′ is formed by the die casting process, the protruding portion 322 does not has the aforesaid slit 324. Accordingly, after punching the base 30 and the heat dissipating fin 32′, the aforesaid indentation 328 will not be formed on the side of the protruding portion 322 either, as shown in FIG. 9. It should be noted that the same elements in FIGS. 8-9 and FIGS. 4-5 are represented by the same numerals, so the repeated explanation will not be depicted herein again.

As mentioned in the above, the invention utilizes the punching process to combine the base and the heat dissipating fin. After the punching process, the side wall of the accommodating recess of the base will deform and then cover at least a part of the protruding portion of the heat dissipating fin, such that the base and the heat dissipating fin are combined with each other tightly. Accordingly, the draft angle of the conventional heat dissipating fin is unnecessary for the heat dissipating fin of the invention. Furthermore, the whole weight of the heat dissipating fin of the invention can be lighter and the height of the heat dissipating fin of the invention can be higher than the prior art. Moreover, the number of heat dissipating fins of the invention can be increased in the heat dissipating device, such that the heat dissipating area can be increased and the heat dissipating efficiency can be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat dissipating device comprising:
a base comprising an accommodating recess formed thereon; and
a heat dissipating fin comprising a heat dissipating portion and a protruding portion, the protruding portion protruding from an end of the heat dissipating portion and being disposed in the accommodating recess, the base and the heat dissipating fin being combined with each other by a punching process, such that a first side wall of the accommodating recess covers at least a part of the protruding portion.

2. The heat dissipating device of claim 1, wherein the protruding portion protrudes from the end of the heat dissipating portion by a drawing process, such that a slit is formed on a side of the protruding portion before the punching process.

3. The heat dissipating device of claim 2, wherein the slit is sealed to form an indentation on the side of the protruding portion after the punching process.

4. The heat dissipating device of claim 3, wherein a second side wall of the accommodating recess is engaged with the indentation after the punching process and the first side wall is opposite to the second side wall.

5. The heat dissipating device of claim 1, wherein two holes are formed on opposite ends of the protruding portion.

6. The heat dissipating device of claim 1, wherein the heat dissipating fin is formed by a die casting process.

7. The heat dissipating device of claim 1, wherein the protruding portion is a strip-shaped structure continuously or not continuously.

8. A method of manufacturing a heat dissipating device comprising:
providing abase and a heat dissipating fin, wherein the base comprises an accommodating recess formed thereon, the heat dissipating fin comprises a heat dissipating portion and a protruding portion, and the protruding portion protrudes from an end of the heat dissipating portion;
disposing the protruding portion in the accommodating recess; and
using a punching head to punch the base and the heat dissipating fin in a punching process, such that a first side wall of the accommodating recess covers at least a part of the protruding portion.

9. The method of claim 8, further comprising:
forming the protruding portion at the end of the heat dissipating portion by a drawing process, such that a slit is formed on a side of the protruding portion before the punching process.

10. The method of claim 9, wherein the slit is sealed to form an indentation on the side of the protruding portion after the punching process.

11. The method of claim 10, wherein a second side wall of the accommodating recess is engaged with the indentation after the punching process and the first side wall is opposite to the second side wall.

12. The method of claim 8, further comprising:
forming two holes on opposite ends of the protruding portion.

13. The method of claim 8, further comprising:
forming the heat dissipating fin by a die casting process.

14. The method of claim 8, wherein the protruding portion is a strip-shaped structure continuously or not continuously.
